(19) United States
(12) Patent Application Publication
(10) Pub. No.: US 2012/0175394 A1
(43) Pub. Date: Jul. 12, 2012

(54) MODULAR RETAINING SYSTEM FOR A MOBILE MULTIMEDIA TERMINAL

(76) Inventor: Dirk Keune, Malsch (DE)

(21) Appl. No.: 13/382,676

(22) PCT Filed: Jul. 6, 2010
(86) PCT No.: PCT/EP10/04063

§ 371 Date: Mar. 26, 2012

Related U.S. Application Data
(63) Continuation of application No. 61/223,115, filed on Jul. 6, 2009.

(51) Int. Cl. H05K 7/00; B60R 7/06; F16M 13/04

(52) U.S. Cl. 224/483; 24/3.1; 24/3.7; 24/3.11

(57) ABSTRACT

A retaining device (1′) for a mobile multimedia terminal (2), such as a pocket PC, smart phone, navigation device, or the like, including: at least one retaining arm (4); a fastening device (5′), arranged at a first end of the retaining arm and which is designed to fasten the retaining arm to an air-conditioning duct cover (11) in the area of the dashboard or the center console (9) of a motor vehicle; a connecting device (14) arranged at the other, second end of the retaining arm for connecting to a receiving and retaining element (6) for the multimedia terminal. The retaining device (1′) is characterized in that the fastening device (5′) includes at least the following elements: at least one elongated anchoring part (15) having at least one hook end (15a), which can be inserted between bars (11a, 11b) of the air-conditioning cover (11), the hook end (15a) being designed to encompass the rear narrow side of at least one bar in a substantially form-closed manner; at least one support part (12) having at least one support element (12′) for being supported outside the air-conditioning cover (11) on the dashboard or the center console, which can be moved (V) relative to the hook end (15a) of the anchoring part (15); a locking device (16) for detachably fixing the relative arrangement of the hook end (15a) and the support part (12). The retaining device is part of a modular component system for the flexible use of modern multimedia terminals.

### BACKGROUND

The present invention relates to a retaining device for a mobile multimedia terminal, such as a pocket pc, a smart phone, a navigation device, or the like, such as an iPhone or iPod touch from the company Apple.

Furthermore, the present invention relates to a receiving and retaining means for a mobile multimedia terminal, such as a pocket pc, a smart phone, a navigation device, or the like, which preferably is used as a modular component within the retaining device mentioned at the outset.

Additionally, the present invention relates to a retaining device for a mobile multimedia device, such as a pocket pc, smart phone, navigation device, or the like comprising:
at least one retaining arm;
retaining means arranged at a first end of the retaining arm, which are embodied to fasten the retaining arm to the air conditioning register in the area of dashboard or the center console of a motor vehicle;
connection means arranged at the other, second end of the retaining arm for the connection to receiving and retaining means for the multimedia terminal.

Finally the present invention also relates to a retaining arm to connect to receiving and retaining means for a mobile multimedia terminal, such as a pocket pc, smart phone, navigation device, or the like, particularly the receiving and retaining means according to the invention for a mobile multimedia terminal.

Presently available multimedia terminals provide their users with a wide spectrum of audio-visual content as well as additional gaming and functional applications and are frequently used as a type of substitute television. Overlapping spectra of applications are also possible: for example, smart phones can also be used as navigation devices.

However, particularly in extended periods of use it must be considered disadvantageous, here, that the user must hold the respective multimedia terminal permanently in a position in his/her field of view considered rather uncomfortable on the long term, which leads to unpleasant stress and/or fatigue of the arm muscles. Additionally, the use of the mobile multimedia terminal mentioned leads to the user only having one hand available over an extended period of time to perform other activities.

This can be remedied by the mobile multimedia terminal being put down in a suitable fashion on an object, such as a pillow or the like. However, this requires the presence of such a suitable object, which particularly is not always given particularly in mobile applications. Additionally, such a solution requires a relatively static sitting or lying position of the user, which is also undesirable on the mid and long term. Additionally, it has shown that depositions or placing down a mobile multimedia terminal, particularly on a pillow, can negatively influence the quality of audio signals, when for example the installed loud speaker is covered partially or entirely.

When using the above-mentioned devices in a motor vehicle it must additionally be ensured that the driver is not distracted from his/her primary activity, namely steering the vehicle, and/or that the respective device remains securely in its place, which usually represents an area of the dashboard and/or the center console, even under acceleration or in curves. In this context, retaining devices are already known for mobile phones, which are held by way of snapping and/or via a type of clip connection to the bars of a ventilation or air-conditioning register of the vehicle. However, such devices are expensive and delicately designed, which regularly leads to damages and coincides with a complicated handling, particularly when removing the retainer from the air-conditioning register.

### SUMMARY

On the one hand, the invention is based on the objective to avoid the above-mentioned disadvantages of a retaining device for a mobile multimedia terminal, which is versatile and suitable for daily use due to its simple and cost-effective design, particularly when driving a motor vehicle, and which allows the user to use particularly the video functions of his/her mobile multimedia terminal in a non-tiring fashion over an extended period of time, without here being compromised in his/her manual options and/or the enjoyment of the audio functions of the device. Furthermore, the mobility of the multimedia terminal shall essentially remain uncompromised.

Furthermore, the invention shall provide a modular component system for retaining multimedia terminals, which allows the flexible use of mobile multimedia terminals in as many possible daily situations as possible without for this purpose in each case a completely different retaining device being required, which would lead to respectively disadvantageous costs and consumption of resources.

This objective is attained in a retaining device according to the invention for a mobile multimedia terminal, exhibiting receiving and retaining means for a mobile multimedia terminal with the features of the invention, with a retaining device for a mobile multimedia terminal with the features of the invention, as well as with a retaining arm to connect retaining and fastening means for a mobile multimedia terminal with the features of the invention.

Advantageous further developments of the invention are objectives of dependent claims, with their wording hereby explicitly being included in the description by way of reference in order to largely avoid unnecessary text repetitions.

According to a first aspect of the present invention a retaining device for a mobile multimedia terminal, such as a pocket pc, smart phone, or the like is embodied as follows: it comprises at least one retaining arm and fastening means arranged at a first end of the retaining arm, which are embodied for the fastening of a retaining arm at a head covering, preferably a common baseball cap or a common headband with a sun visor. Here, the fastening occurs such that the retaining arm extends from the head covering towards the front in the direction of view of the user wearing said head covering. At the other, second end of the retaining arm receiving and retaining means are provided for the multimedia terminal. Furthermore, the receiving and retaining means for the multimedia terminal are arranged or adjustable in reference to the retaining arm such that at least the graphic display device, i.e. the panel of the multimedia terminal received and held in the receiving and retaining means is located essentially centrally in the field of view of the user after the retaining arm was fastened at the head covering.

According to a second aspect of the present invention this represents a receiving and retaining means for a mobile multimedia terminal, such as a pocket pc, smart phone, navigation device, or the like, which comprise fastening means for a detachable connections to a retaining arm, preferably the retaining arm of the device according to the first aspect of the present invention. The retaining means can particularly be arranged at the rear, while the receiving and retaining means for the multimedia terminal most preferably are embodied as a retaining cup, into which the multimedia terminal can be inserted or clipped in.

According to a third aspect the present invention represents a retaining device for a mobile multimedia terminal, such as a pocket pc, smart phone, navigation device, or the like, initially comprising the following features:
at least one retaining arm;
retaining means arranged at a first end of the retaining arm, embodied to fasten the retaining arm to the air-conditioning register in the area of the dashboard or the center console of a motor vehicle;
at the other, second end of the retaining arm connection means are arranged for the connection to receiving and retaining means for the multimedia terminal, which receiving and retaining means preferably being embodied according to a second aspect of the present invention;

characterized in that the retaining means at least comprising the following elements:
at least one oblong anchoring part with at least one hooked end, which can be guided between two bars of the air-conditioning register, with the hooked end essentially being embodied to encompass the rear narrow side of at least one bar;
at least one support part with at least one support element for supporting on the dashboard or a center console, which is displaceable in reference to the hooked end of the anchoring part;
locking means for a detachable fixation of the relative arrangement of the hooked end and the support part.

Within the scope of the above-mentioned modular component system the present invention provides, according to a fourth aspect, an additional retaining arm for the connection to receiving and retaining means for a mobile multimedia terminal, such as a pocket PC, smart phone, navigation device, or the like, particularly for the connection to the above-mentioned receiving and retaining means according to the second aspect of the present invention.

According to a fundamental idea of the first aspect of the present invention the suggested retaining device comprises therefore at least one retaining arm to be fastened at a head covering. The above-mentioned head covering may here either itself be a part of a retaining device according to the invention or may represent a commercial object, independent and separate therefrom, for example in the form of a baseball cap or the like.

The retaining arm is therefore fastened at one of its end at the head covering and carries at its other end the above-mentioned receiving and retaining means for the multimedia terminal, by which the latter is fastened to the retaining arm. The multimedia terminal itself is not part of the present invention. In general, any commercially available multimedia terminal may be used with the retaining device according to the invention based on the first aspect of the present invention.

As already explained, the retaining arm of the retaining device according to the invention based on the first aspect of the present invention, after fastening to the head covering, extends forwardly in the direction of view of the user and the receiving and retaining means for the multimedia terminal are arranged at the front end of the retaining arm and/or appropriately adjustable such that subsequently the display of the multimedia terminal is located in the middle of the field of view of the user so that he/she can easily observe the above-mentioned display with a relaxed position of the head without using his/her hands.

In this context, the features according to which the above-mentioned fastening means are arranged at one end of the retaining arm shall be understood such that the fastening means are either provided at the retaining arm itself, thus quasi form a part of the retaining arm, or that the fastening means are provided otherwise, e.g., at the head covering, and affect the retaining arm from the outside only, with here they are also arranged thereat.

In particular with regards to the embodiment of at least one retaining arm, there are various options within the scope of the present invention, which in the following shall be discussed in greater detail also with reference to the attached drawing and the respective description of figures.

In order for the multimedia-experience to be enjoyed as desired, in light of presently common dimensions of typical multimedia terminals, such as iPhones or iPod tough of the company Apple, a first further development of the fastening device according to the invention based on the first aspect of the present invention provides that the retaining arm, preferably when suitable adjustment options are implemented, particularly an extension of shortening, is embodied such that the receiving and retaining means for the multimedia terminal shows a distance from 10 cm to 40 cm, preferably from 15 cm to 30 cm from the eye of the user.

Independent therefrom, the retaining device according to the first aspect of the present invention, within the scope of another further development, may have two parallel arranged, essentially identical retaining arms, with the receiving and retaining means for the multimedia terminal being arranged at its second end in order to improve the stability of the arrangement.

Another further development of the retaining device according to the invention based on a first aspect of the present invention provides that the receiving and retaining means for the multimedia terminal is fastened at the retaining arm in an articulate fashion in order to allow a multitude of adjustment options for the orientation of the display device of the multimedia terminal. In this context, for example the use of a ball-and-socket joint or a pivot joint may be provided between the retaining arm and the above-mentioned receiving and retaining means. Alternatively retaining arms and receiving/retaining means may be embodied in one piece.

Advantageously the receiving and retaining means are embodied as a receiving cup, in which the multimedia terminal can be laterally inserted and/or clipped in. Separate receiving and retaining means may be provided for each different type of multimedia terminal, sized according to the dimensions of the multimedia terminals.

Alternatively, it may also be provided that the receiving and retaining means for the multimedia terminal are adjustable to the differently sized multimedia terminals.

Furthermore, the receiving or retaining means for the multimedia terminal may be fastened to the retaining arm in a detachable fashion, with in this context particularly the use of a screw connection must be considered. However the present invention also includes embodiments in which the above-mentioned receiving and retaining means and at least one retaining arm are connected to each other in one piece, in a form-fitting fashion, or by other means.

At least one retaining arm may also show a joint within the scope of another embodiment of the first aspect of the present invention, so that the receiving and retaining means for the multimedia terminal can be moved (pivoted) out of the field of view of the user, when necessary.

Another further development of the retaining device according to the invention based on the first aspect of the present invention provides for the retaining arm being embodied flexibly, at least sectionally, preferably in a bendable, semi-stiff fashion like a gooseneck or the like. This way, a need-based positioning of the multimedia terminal can also be achieved.

At least one retaining arm must be embodied in a non-straight fashion, but within the scope of a respective further development according to the first aspect of the present invention it may comprise at least one angle or bend in the area of its second end in order for the receiving and retaining means for the multimedia terminal being positioned already in the desired fashion in the field of view of the user. Here, the size of the angle and/or bend preferably ranges from 70° to 110° and most preferably amounts to approximately 90°.

At least the retaining arm of the retaining device according to the invention based on the first aspect of the present invention, in an appropriate further development, may be embodied at least essentially flat or alternatively showing a round cross-section. Potential materials particularly for the retaining arm of the retaining device according to the invention based on the first aspect of the present invention are plastic and/or metal.

A particularly preferred further development of the retaining device according to the invention based on the first aspect of the present invention provides for the fastening means to be embodied as clamping means with at least two spring-elastic clamping parts acting opposite each other, by which the retaining arm can be fastened in a clamped position to a visor, shade, brim or the like of a preferably common head covering.

In the simplest case the retaining device according to the first aspect of the present invention can therefore be pushed upon the visor of a conventional baseball cap, for example. For light devices and/or in general, here a single-arm embodiment of the retaining arm is possible, laterally fastened at the cap visor, with its front end may be bent into the field of view of the user. The retaining arm may additionally exhibit a pivotal joint for a lateral folding away.

Alternative variants for fastening the retaining device and/or the retaining arms at the head covering comprise according to the first aspect of the present invention, among other things, screw connections, rivet connections, adhesions, VELCRO™ connections, as well as sewed connections, preferably in the area of the visor of a conventional baseball cap.

Another preferred further development of the retaining device according to the invention based on the first aspect of the present invention provides however that the fastening means show at least one perforation in the retaining arm as well as connection means that can be passed through said penetration, preferably screws, which cooperate with at least one complementary structure, preferably a matching penetration in the visor, shade, or brim area of an otherwise preferably common head covering, in order to fasten the retaining arm at said head covering, with the retaining device most preferably additionally comprising a respectively embodied head covering. Alternatively a suitable structure to be connected to the fastening means may be provided at the head covering, for example a threaded structure or a latching structure for a snap connection with suitable latching means.

Alternatively, the fastening means, as already indicated, may also be embodied in the form of a VELCRO connection, with for example at the retaining arm a suitable hook material being provided, particularly glued on, while the respective looped material being provided at the head covering, particularly at the top and/or bottom of the visor, sun shade, or the like. Of course, the inverse application is also possible.

Another further development of the retaining device according to the invention based on the first aspect of the present invention provides that the fastening means comprise a bent, hook-shaped structure in reference to the extension of the retaining arm, which is embodied to engage a suitable structure, preferably an adjustment tape or the like provided in the area of the back of the head covering, in order to fasten the retaining arm at the head covering, with the retaining arm comprising at least one section shaped complementary to the head covering between the fastening means and its second end. Here, too, the retaining device may most preferably comprise additionally an appropriately embodied head covering, which shows the above-mentioned engagement structures.

Another further development of the retaining device according to the invention based on the first aspect of the present invention is characterized in an otherwise essentially commercial head covering, though, preferably a baseball cap or a headband, each comprising tunnels respectively extending laterally approximately at the height of the temples towards the back of the head, into each of which a retaining arm of the retaining device being inserted, with the retaining arms preferably being mobile within said tunnel, most preferably between an inserted resting position and a projected operating position. The two tunnels may also be combined to a joint tunnel, extending around the area of the back of the head and respectively opening in the frontal lateral area of the head covering.

Instead of a tunnel, alternative insert means may also be used for the retaining arms, e.g., rings, eyelets, loops, or the like. A VELCRO connection of the retaining arms at the side of the head covering is also possible, with e.g., the hook material being provided at the interior side of the retaining arm and the looped material provided laterally at the head covering, or vice versa.

All embodiments of the retaining device according to the invention based on the first aspect of the present invention have in common that they may additionally comprise a loud speaker device or a so-called sound system, which is preferably embodied in the form of head phones and which is provided for the fastening at the retaining arm or at the head covering, with the loud speaker device preferably cooperating with the mobile multimedia terminal in a signaling fashion to issue audio signals of the multimedia terminal.

Within the scope of a particular further development of the retaining device according to the first aspect of the present invention the retaining arm may be embodied, at least partially, by an extended embodied structure of the head covering, such as a visor or the like extended towards the front.

Another further development of the retaining device according to the first aspect of the present invention provides that for a detachable connection of the receiving and retaining means for the multimedia terminal via the retaining arms at least one pin-like connection part is provided, which can be inserted in aligned penetrations at the receiving and retaining means, on the one side, and at the retaining arm on the other side, in order to couple the retaining arm to the receiving/retaining means in a detachable fashion. Here, it may further be provided that at least one recess is provided at the rear of the receiving and retaining means for a partial receiving (inserting) of the connection part in the direction of its longitudinal extension such that the connection part in its inserted state extends at a finite angle, preferably ranging from 30° to 150°, most preferably from 60° to 120°, or approximately 90° in reference to the back of the receiving and retaining means.

This way, a support option is provided, with the connection part acting as the support means such that the multimedia terminal, after the removal of the retaining arm, can be placed onto a planar surface together with the receiving and retaining means like a table fastener under a beneficial observation angle. Of course, the support means can also be embodied as a separate component without the above-described connecting function. For reasons of stability an embodiment with more than one support means may also be beneficial.

Another further development of the retaining device according to the first aspect of the present invention provides that at least one deflectable support part is provided at the rear of the receiving and retaining means, which extends in its deflected state at a finite angle, preferably from 30° to 150°, most preferably from 60° to 120°, or approximately 90° in reference to the rear of the receiving and retaining means. Such a deflected, foldable support part may be used additionally (as a second support part) or as an alternative to the variant described above. Here, particularly the protection from getting lost is advantageous.

According to one fundamental idea according to the second aspect of the present invention the suggested receiving and retaining means for a mobile multimedia terminal, such as a pocket pc, smart phone, navigation device, or the like comprises connection means for the detachable connection to a retaining arm, preferably the retaining arm of the device according to the first aspect of the present invention described above in greater detail in the sense of the discussed modular system of components. Preferably the above-mentioned connection means are arranged at the rear of the receiving and retaining means, i.e. at the side facing away from the graphic display device of an accepted multimedia terminal. Here, the receiving and retaining means for the multimedia terminal may be embodied as fastening cups into which the multimedia terminal can be inserted or clipped in.

A further development of the receiving and retaining means according to the second aspect of the present invention provides for the connection means to be embodied for an articulate connection with the retaining arm, preferably like a pivotal or ball-and-socket joint. In this context, for the detachable connection of the retaining arm and the receiving means once more the above-mentioned pin-shaped connection part may be used, as described above.

Other further developments of the receiving and retaining means according to the second aspect of the present invention provides that a table fastening is also possible via the receiving and retaining means, as described above in greater detail.

According to the principle idea of the third aspect of the present invention a fastener for an air-conditioning register is created for the use in a motor vehicle, with the components of the respective retaining device, particular the receiving and retaining means for the multimedia terminal can be used here, within the scope of the modular concept of the present invention.

For the function of the retaining device according to the third aspect of the present invention it is here necessary that it is not only passing through the oblong anchoring part with to at least one hooked end, which can be guided between the bars of the air-conditioning register, with the hooked end being embodied for an essentially form-fitting encompassing of the rear narrow side of at least one bar, in order to be held at the relatively thin bars, as known from prior art, but that at least one additional support part is provided having at least one support element to rest on the dash board or the center console, thus a portion of the retained load is compensated by the considerably more stable components of the dashboard and/or center console. The support part is displaceable in reference to the hooked end of the anchoring part in order to tighten the retaining device in reference to the dashboard and/or center console on the one side and at least one bar at the other side. Here, contrary to the purely bar-based fixation of prior art, particularly the trend for vibration of the arrangement is largely reduced. The above-mentioned fixation means ensure a detachable fixation of the relative arrangement of the anchoring part and/or hooked ends and the support part, depending on the desired strength of retaining force or for the removal of the arrangement.

A further development of the retaining device according to a third aspect of the present invention provides that the retaining arm and the anchoring part are embodied in one piece, with the retaining arm at its second end being embodied as a hooked element, forming a particularly simple and stable arrangement. In other words, the retaining arm that can be connected within the scope of the modular concept of the invention to the receiving and retaining means and the anchoring part may represent the very same components, with its ends being shaped appropriately. Beneficially, this component extends in a displaceable fashion through the above-mentioned support part in order to this way allowing by a suitable displacing to reach the desired relative arrangement of the anchoring part and/or the hooked end and the support part. This also depends on the type, size, and geometry of the air-conditioning register, the depth of its bars, etc. Alternatively a division of the above-mentioned component into two parts may be advantageous, for example without limitations via interior and/or exterior threads in order to realize a screwed connection, because this way type adjustable lengths of the component can be achieved dependent on the size, and geometry of the air-conditioning register as well as the depth of its bars, which improves the range of application of the suggested retaining device.

Another further development of the retaining device according to the third aspect of the present invention provides that the anchoring part is arranged rotational in reference to the support part, e.g., via a simple rotary guide. This way, the user can freely decide if the anchoring of the retaining device shall occur at the vertical bars or at the horizontal bars of the air-conditioning register, with here he/she beneficially will select the respective bars embodied stronger, depending on type, size, and geometry of the air-conditioning register.

Another further development of the retaining device according to the third aspect of the present invention provides that the support part comprises several support arms, preferably three to six support arms, which are mounted to a common fastening structure in a preferably articulate fashion. In this context particularly preferred are four support arms, with two of them each being embodied straight in one piece, so that overall a cross-shaped or X-shaped arrangement with four support points results. According to the fundamental rules of geometry, three support points already define a plane (for example in case of Y-shaped arms) so that this way a secure support is ensured even at greater accelerations. The articulate arrangement allows a flexible adjustment to the geometry of the air-conditioning register, with here within the scope of the invention it is attempted to implement any support for reasons of stability outside the actual air-conditioning register. At the free ends of the above-mentioned arms, at the side facing the dashboard, one support element each may be arranged, with the support elements preferably being cushioned, particularly by a foam rubber element or the like in order to prevent damages of the vehicle interior and to reduce vibrations.

Another further development of the retaining device according to the third aspect of the present invention provides that the support arms are each embodied adjustable within their length and/or with regards to the angle formed between them, particularly by a pivoting in reference to the fastening structure. This way it is additionally ensured that any support occurs outside the air-conditioning register for reasons of stability.

Another further development of the retaining device according to the third aspect of the present invention provides that the support part and particularly the support arms are embodied in a spring-elastic fashion in the direction of displacement with regards to the anchoring part, and in order to achieve a secure tightening of the retaining device. Advantageously, for this purpose the arms are embodied in a curved fashion, with the curvature facing the support area (dashboard, console).

Another further development of the retaining device according to the third aspect of the present invention provides for the anchoring part to comprise a predetermined breaking point in the area of the hooked end. This ensures that no expensive damages of the air-conditioning register develop when for example the retaining device is excessively tightened or is excessively stressed (laterally) during use. The anchoring part may represent a low-cost single-use and/or exchangeable part so that subsequent costs are minimized when damaged.

Another further development of the retaining device according to the third aspect of the present invention provides that the fastening means are embodied as screw elements, which are preferably arranged on the support part and affect the anchoring part. Alternatively it may be provided that the fastening means are embodied as spring-loaded latching means, which preferably are arranged on the support part and affect complementary structures of the anchoring part. Of course, other possible embodiments may also be used for the detachable fixation of the relative arrangement of the anchoring part and/or the hooked ends and the support part, for example in the form of a clamping mechanism, via fixation pins, magnetic fixation, via geared threads, or the like.

Another further development of the retaining device according to the third aspect of the present invention provides that the hooked ends comprise a multitude of hooked elements, preferably two hooked elements, which may be arranged side-by-side like the tongue of a snake. This way, the trend for a lateral tipping of the arrangement is reduced. Additionally the respective bar of the air-conditioning register at which the arrangement is tightened to is locally stressed to a lesser extent.

The hooked end may be sized such that it undercuts more than one bar of the air-conditioning register in order to better distribute the retaining force. Here, another further development of the retaining device according to the third aspect of the present invention provides that the hooked end is embodied in a folding fashion, in particular by the provision of a suitable flip and/or spring mechanism so that after insertion between the bars it is unfolded and thus engages therebehind. Most preferably the above-mentioned folding mechanism is embodied in a reversible fashion, in order to allow removing the hooked end from the air-conditioning register.

Another further development of the retaining device according to the third aspect of the present invention provides that at least the support part is embodied from plastic, preferably polyamide without fiberglass reinforcement or a similar material, allowing the overall construction to be realizable in a weight saving and cost-effective fashion.

### BRIEF DESCRIPTION OF THE DRAWINGS

Additional features and advantages of the present invention are discernible from the following description of exemplary embodiments with reference to the drawing.

FIG. 1a to 1h show various illustrations and implementations of a first embodiment of the retaining device according to the invention based on the first aspect of the present invention;

FIG. 2a to 2h show various illustrations and implementations of a second embodiment of the retaining device according to the invention based on the first aspect of the present invention;

FIG. 3a to 3h show various illustrations and implementations of a third embodiment of the retaining device according to the invention based on the first aspect of the present invention;

FIG. 4a to 4h show various illustrations and implementations of a fourth embodiment of the retaining device according to the invention based on first aspect of the present invention;

FIG. 5a to 5e show various illustrations and implementations of a fifth embodiment of the retaining device according to the invention based on the first aspect of the present invention;

FIG. 6a to 6g show various illustrations and implementations of a sixth embodiment of the retaining device according to the invention based on the first aspect of the present invention;

FIG. 7 to 7i show various illustrations and implementations of a seventh embodiment of the retaining device according to the invention based on the first aspect of the present invention;

FIG. 8a to 8f show various illustrations and implementations of an eighth embodiment of the retaining device according to the invention based on the first aspect of the present invention;

FIG. 9a to 9c show various illustrations and implementations of a ninth embodiment of the retaining device according to the invention based on the first aspect of the present invention;

FIG. 10a to 10c show various illustrations and implementations of an embodiment of the retaining device according to the invention based on the third aspect of the present invention;

FIG. 11a to 11c show various illustrations and implementations of an embodiment of the receiving and retaining means according the second aspect of the present invention.

### DETAILED DESCRIPTION OF THE PREFERRED EMBODIMENTS

When in the following, each time summarizing, “Fig. X” is discussed, here generally all allocated partial figures “Fig. Xy” are included, with y=a, b, c . . . .

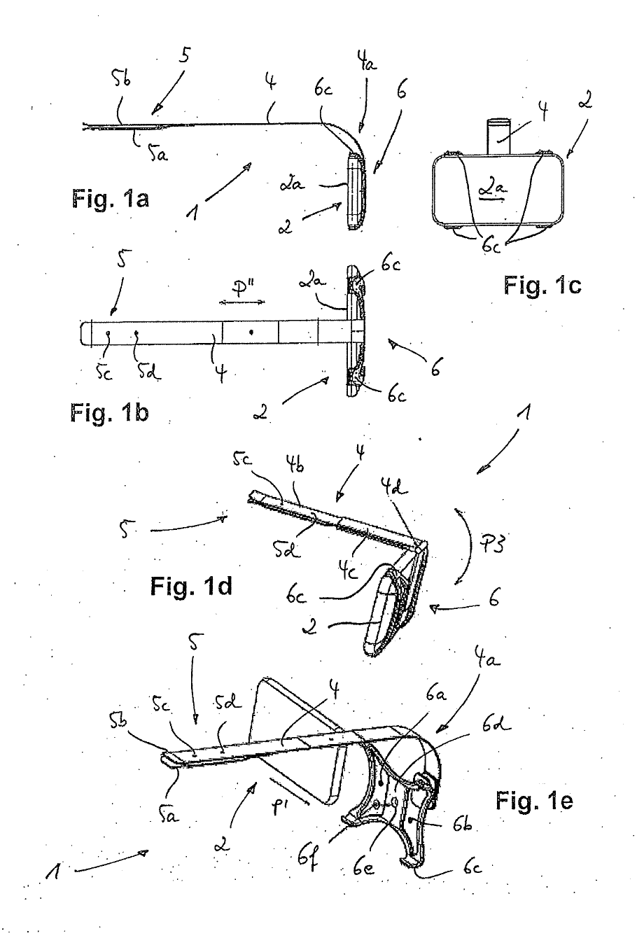

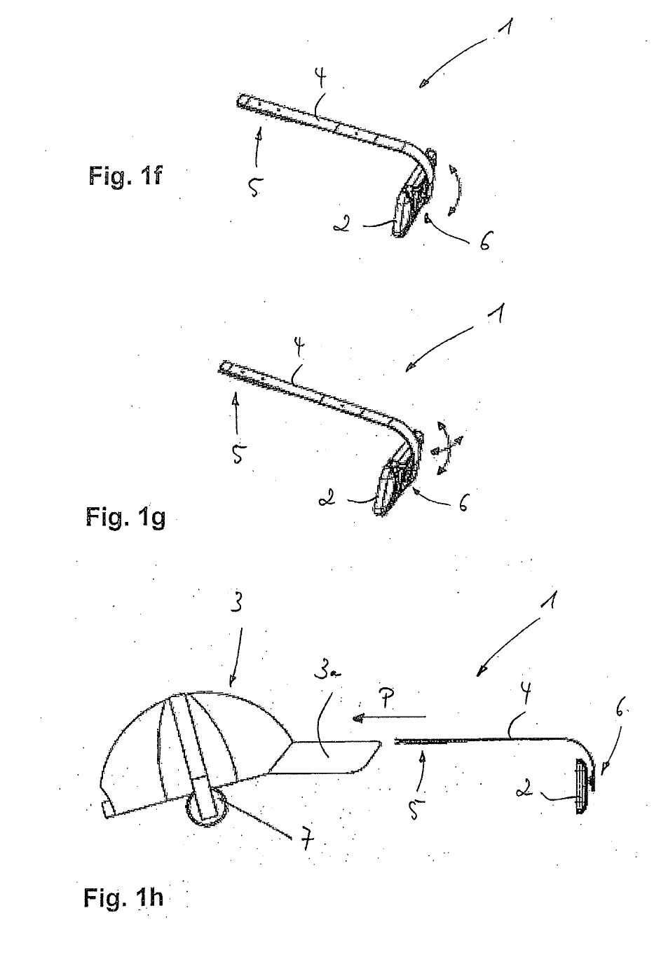

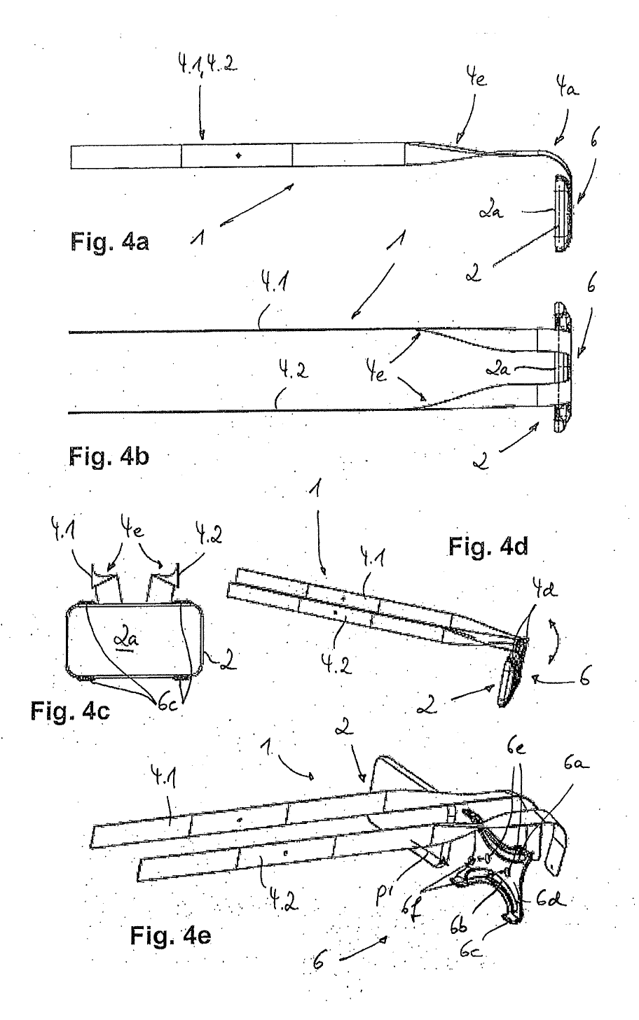

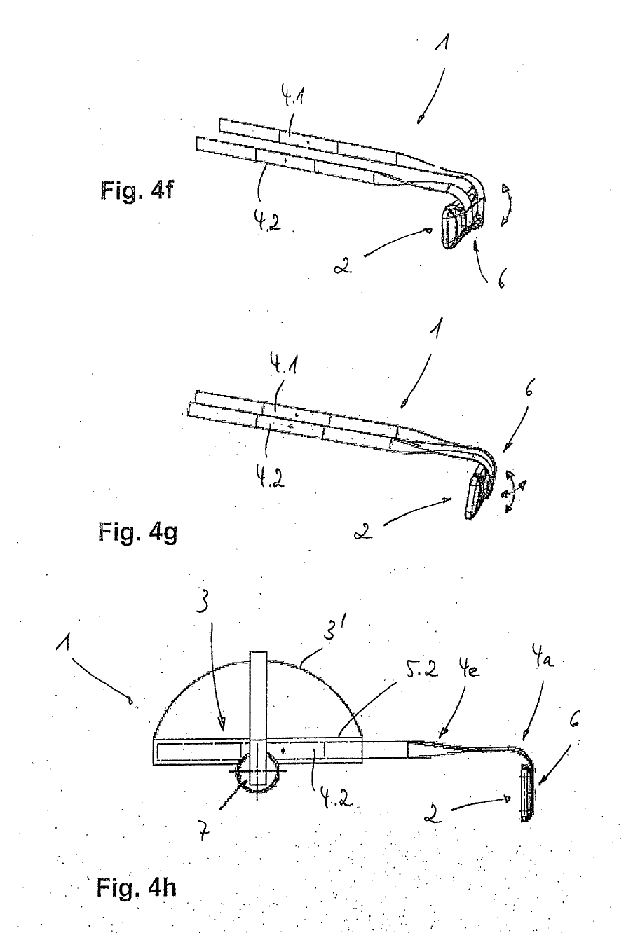

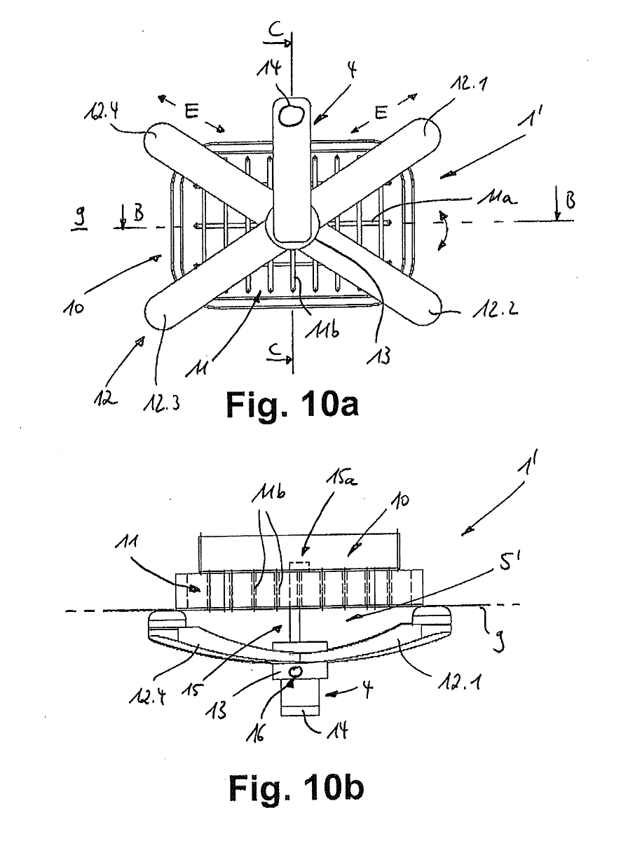

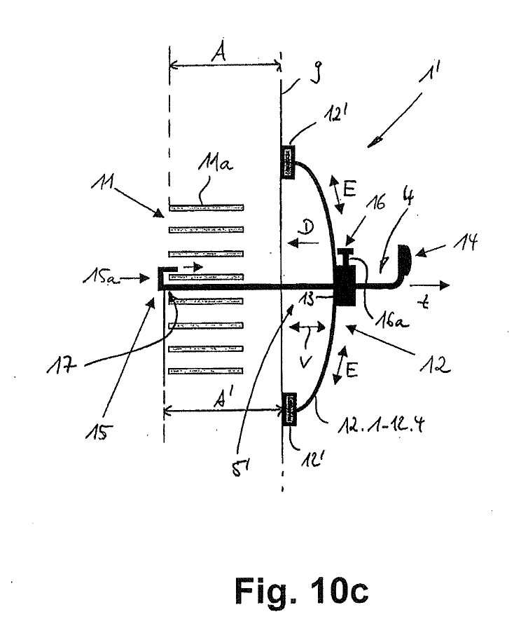

The retaining device according to the invention is marked in FIGS. 1 through 11 overall with the reference character 1 (first aspect of the present invention) and/or 1′ (third aspect). It serves to the fastening of a mobile multimedia terminal 2, such as a pocket pc or a smart phone, which is not a component of the actual retaining device 1, 1′, at a head covering 3, which preferably and without restriction may essentially be embodied in the form of a commercial baseball cap (FIGS. 1 through 3 and 5 through 9) or like a headband (FIG. 4), and/or fastened at an air-conditioning register of a motor vehicle (FIG. 10).

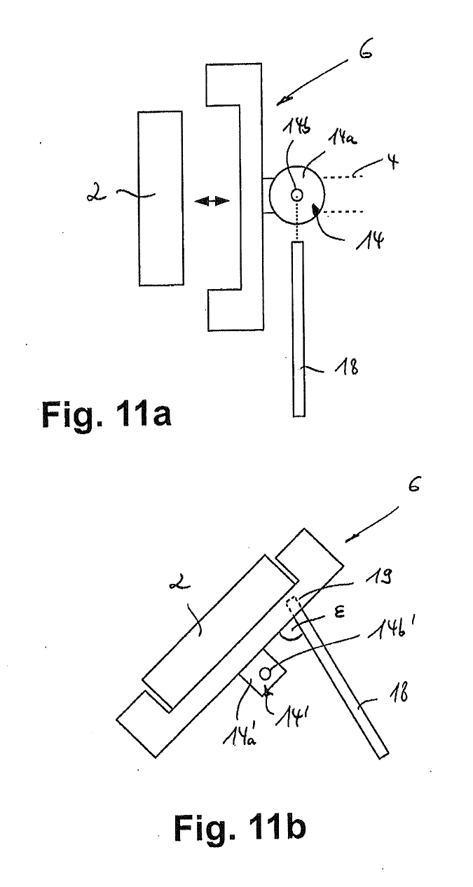

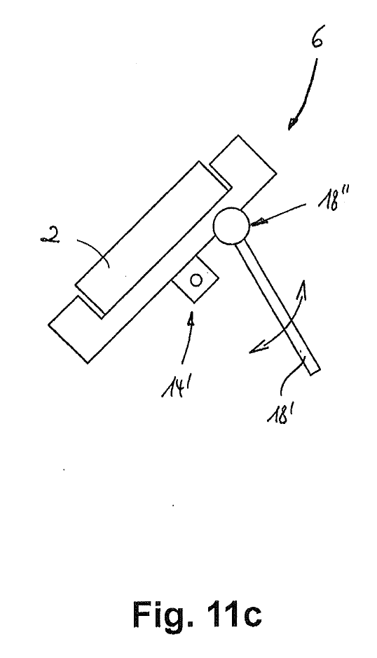

A retaining device 1, 1′ according to the invention respectively comprises at least one receiving and retaining means each, in which a multimedia terminal is arranged in a detachable fashion. This receiving and retaining means can be separately sold as a modular system component and is shown in FIG. 11 as a separate unit. Furthermore, each retaining device according to the invention comprises a retaining arm, with fastening means being arranged at one of its ends serving to fastening the retaining arm to a desired fastening object, which may represent either a head covering or an air-conditioning register of a motor vehicle. With its other end the retaining arm is and/or can be connected to the so-called receiving/retaining means. The retaining means may be an integrated component of the retaining arm, or they may be present as a separate and perhaps interchangeable unit. Within the scope of the modular invention concept this way different and flexibly used fastening arrangements can be realized from the (functional) units fastening means, retaining arm, and receiving/retaining means for various applications, which is explained in detail via an example.

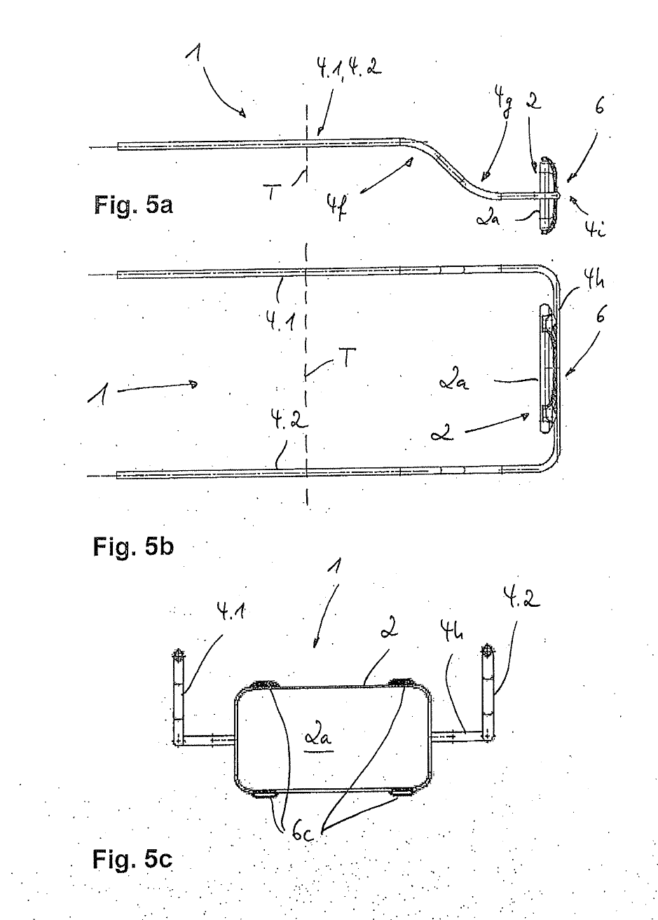

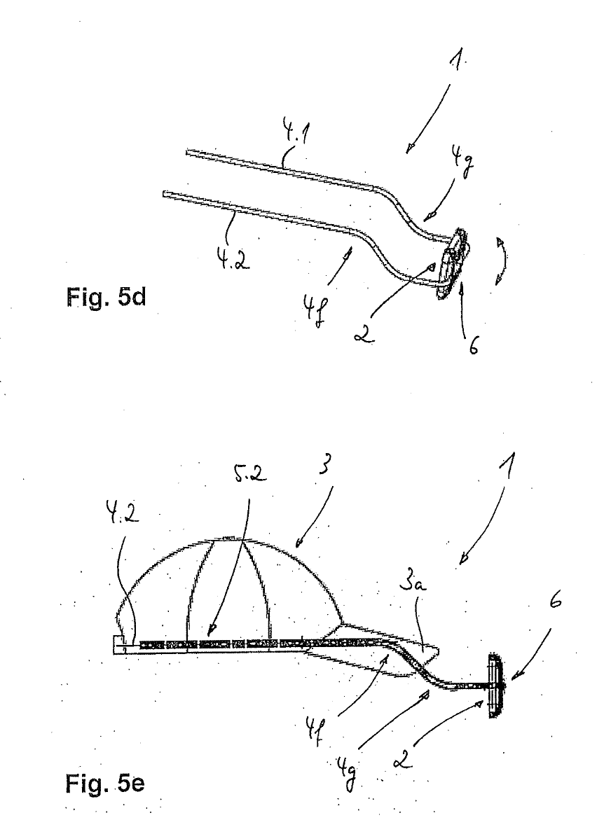

The already discussed head covering 3 may in turn represent a component of the retaining device 1 according to the invention, particularly when special constructive changes are required at the head covering 3, such as in case of the embodiments according to FIG. 4 and FIG. 5.

In particular, the retaining device 1, 1′ according to the invention is suitable for use with an iPod touch or the iPhone of the company Apple, however it is not restricted thereto.

The retaining device 1 comprises, for example according to FIG. 1, at least one retaining arm 4, with fastening means 5 being arranged at one end serving to fasten the retaining arm 4 at the head covering 3. At the other end of the retaining arm 4 the receiving and retaining means 6 are provided for the multimedia terminal 2.

The retaining arm 4 shall be fastened at a head covering 3 with the fastening means 5 such that the retaining arm 4 extends towards the front, from the head covering 3 in the direction of view of the user wearing said head covering 3. Here, the receiving and retaining means 6 for the multimedia terminal 2 are arranged and/or adjustable in reference to the retaining arm 4 such that at least the graphic display device, i.e. the monitor or the display 2a of the multimedia terminal 2 is essentially located centered in the field of view of the user after fastening of the retaining arm 4 at the head covering 3.

The “free length” of the retaining arm 4, i.e. the distance between the fastening means 5 and the receiving and retaining means 6 for the multimedia terminal 2 is here preferably measured such that the display device 2a of the multimedia terminal 2 shows a distance from 10 cm to 40 cm, preferably from 15 cm to 30 cm from the eye of the user when the multimedia terminal 2 is received and retained in the receiving and retaining means 6.

These features are present in a functionally similar form in all embodiments of the retaining device 1 according to the invention based on FIGS. 1 through 9. In the following the individual embodiments of the retaining device according to the invention shall be explained in greater detail using the individual figures and/or details of said figures.

The embodiment according to FIG. 1, comprising the details 1a through 1h, shows a first, particularly simple embodiment of the present invention.

According to the side view in FIG. 1a the individual retaining arm 4, embodied in the form of a flat tape, comprises at one end fastening means 5 acting as opposite clamping means with at least two oppositely acting spring-elastically clamping parts 5a and 5b. Using the clamping parts 5a, 5b the retaining arm 4 according to the illustration in FIG. 1h can be pushed in the direction of the arrow P from the front onto the visor 3a of an otherwise commercial baseball cap 3 in order to fasten the retaining device 1 in a clamping fashion at the baseball cap 3. Of course, in this context the invention is not limited to the use with a baseball cap, but in principle it can be fastened at any visor, shade, or brim of an otherwise commercial head covering 3.

At its other end, the retaining arm 4 is provided with a bend 4a such that it extends in this area at an angle of approximately 90° in reference to its primary direction of extension. At the end of the retaining arm 4 opposite the fastening means 5 the above-mentioned receiving and retaining means 6 are arranged for the multimedia terminal 2. They are embodied like a holding cup, at least partially laterally encompassing the multimedia terminal 2, such as easily discernible from FIGS. 1d and 1e. Preferably, the multimedia terminal 2 can be laterally inserted into the receiving and retaining means 6 according to the arrow P′ in FIG. 1e, without the invention here being limited to such an embodiment, though. Alternatively the receiving and retaining means 6 may also be embodied in the form of a clamping cup, into which the multimedia terminal 2 can be clipped in. Furthermore, the receiving and retaining means 6 may also be embodied adjustable with regards to their width, for example, in order to quasi fixate any inserted multimedia terminal 2 by a subsequent adjustment of the receiving and retaining means.

In the present case, the receiving and retaining means 6 are embodied with approximately X-shaped interior penetrations 6a, 6b and encompass the inserted multimedia terminal laterally via four slightly inwardly curved retaining projections 6c, cushioned in an advantageous fashion.

A bar 6d arranged in the center of the receiving and retaining means 6 comprises a central penetration 6e in the form of a bore, according to FIG. 1e, by which the receiving and retaining means 6 can be fixed via a connection element 6f, preferably in the form of a screw, at the end of the retaining arm 4 provided for this purpose and appropriately embodied.

For this purpose, the retaining arm 4 comprises at its end, cooperating with the receiving and retaining means 6, suitable complementary connection means which are not explicitly shown in the figures for reasons of clarity, for example a bore with an internal thread.

As discernible for one trained in the art the present invention is by no means restricted to the connection between the retaining arm 4 and the receiving and retaining means 6 shown in FIG. 1e as an example. Alternatively the connection in this area may also occur by way of adhesion or in any other material-fitting fashion, for example. Furthermore, the receiving and retaining means 6 may also be embodied in one piece with the retaining arm 4. A connection by way of clamping, insertion, snapping, or via a VELCRO tape may also be considered, here.

As easily discernible from a review of FIG. 1b, the retaining arm 4 may be embodied in its straight section (cf. FIG. 1a) in several parts so that in the longitudinal direction the retaining arm 4 is embodied in a longitudinally adjustable fashion in the direction of the dual arrow P″. For example, the part of the retaining arm 4 (left in FIG. 1b) arranged towards the head covering 3 may be inserted in the remaining part of the retaining arm 4 (right in FIG. 1b) so that the above-mentioned ability for displacement and/or adjustment results in the direction of the dual arrow P″. Such an embodiment is discernible from FIG. 1d, for example. Here, the retaining arm 4 comprises a first part 4b, which also shows the fastening means 5, and a second part 4c, which shows two parallel extending legs, between which the first part 4b is accepted in a displaceable fashion. Furthermore, according to FIG. 1d, the above-mentioned bend 4a of the retaining arm 4 is formed by a link 4d, adjustable in the direction of the dual arrow P3, so that the multimedia terminal 2, accepted in the receiving and retaining means 6, can be deflected upwardly out of the field of view of the user, when necessary (cf. the illustration in FIG. 1h).

The perspective views in FIGS. 1f and 1g show further developments of the above-described embodiment in which the receiving and retaining means 6 and thus the multimedia terminal 2 is arranged at the retaining arm 4 in a pivotal fashion in the direction of the respective dual arrows. Preferably, for this purpose the receiving and retaining means 6 comprise a link, not shown in greater detail, particularly a hinge or a ball-and-socket joint so that the above-mentioned adjustability results with regards to the retaining arm 4.

Again referencing FIG. 1h, the retaining device 1 may additionally and optionally comprise a sound system 7, particularly in the form of headphones, cooperating with the multimedia terminal in terms of signaling in order to allow the user receiving audio signals from the multimedia terminal 2. The cooperation may occur wired or wireless. The sound system 7 may be an integral component of the head covering 3, which for this purpose is appropriately designed. Alternatively the sound system 7 may also be provided as a separate component of the retaining device 1, apart from the head covering 3.

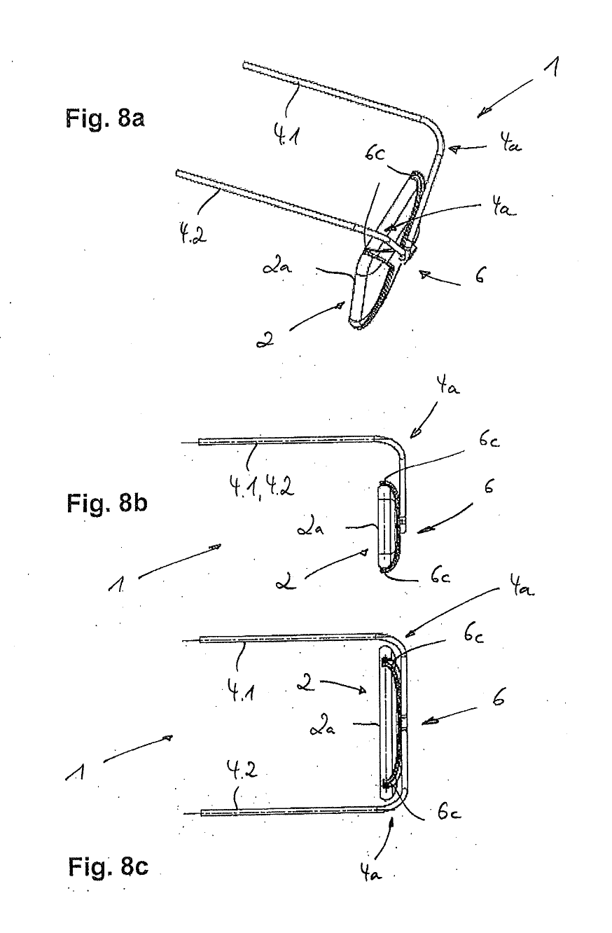

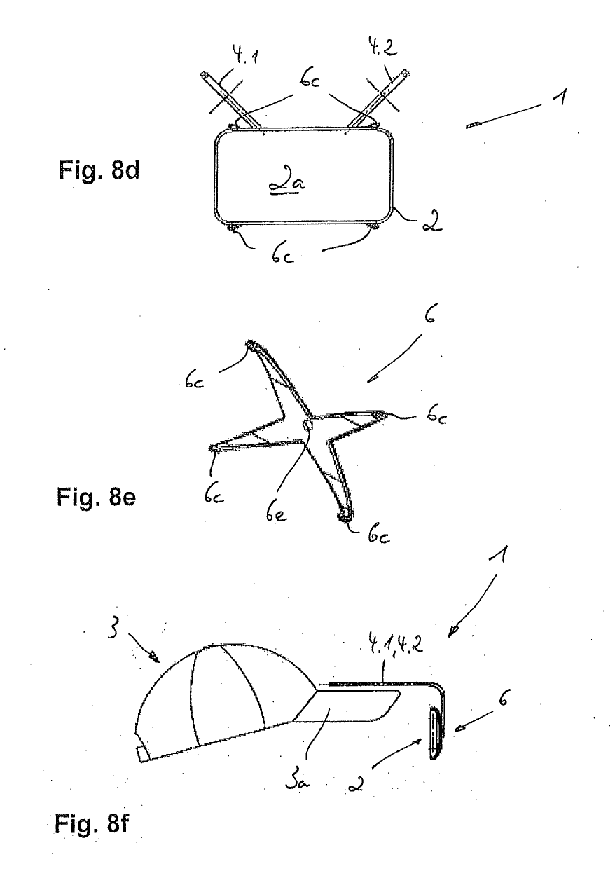

Advantageously, based on FIGS. 1a through 1h, the essential components of the retaining device 1 according to the invention are made from plastic to the extent possible and useful without the present invention being limited thereto, though. However, for certain components of the invention an embodiment comprising (light) metal is also possible. Particularly the receiving and retaining means 6 may also be made from metal, particularly aluminum, in a preferred embodiment of the present invention (cf. FIG. 8).

Particularly FIG. 1b shows other optional fastening means 5c, 5d in the form of penetrations (holes) in the retaining arm 4 and/or the upper clamping part 5b. Connection means, e.g., in the form of screws, can be inserted through the holes 5c, 5d into suitable complementary structures in the head covering 3, e.g., in respective penetrations in the visor 3a (FIG. 1b) in order to fixate the retaining arm 4 at the head covering 3. The bottom clamping part 5a may here be waived. Furthermore, the above-mentioned connection means can also be used in a conventional head covering, of course, in order to increase the clamping force.

When using the device 1 with the fastening means 5 it is simply pushed in the direction of the arrow P onto the visor, the shade, or the brim of the head covering 3, as discernible from FIG. 1h, and is here held by the fastening means 5. A multimedia terminal 2, held by the receiving and retaining means 6, is then positioned in a pleasant distance in the middle of the field of view of the user so that he/she can relaxed observe the display device 2a of the multimedia terminal 2 in a relaxed manner without using his/her hands.

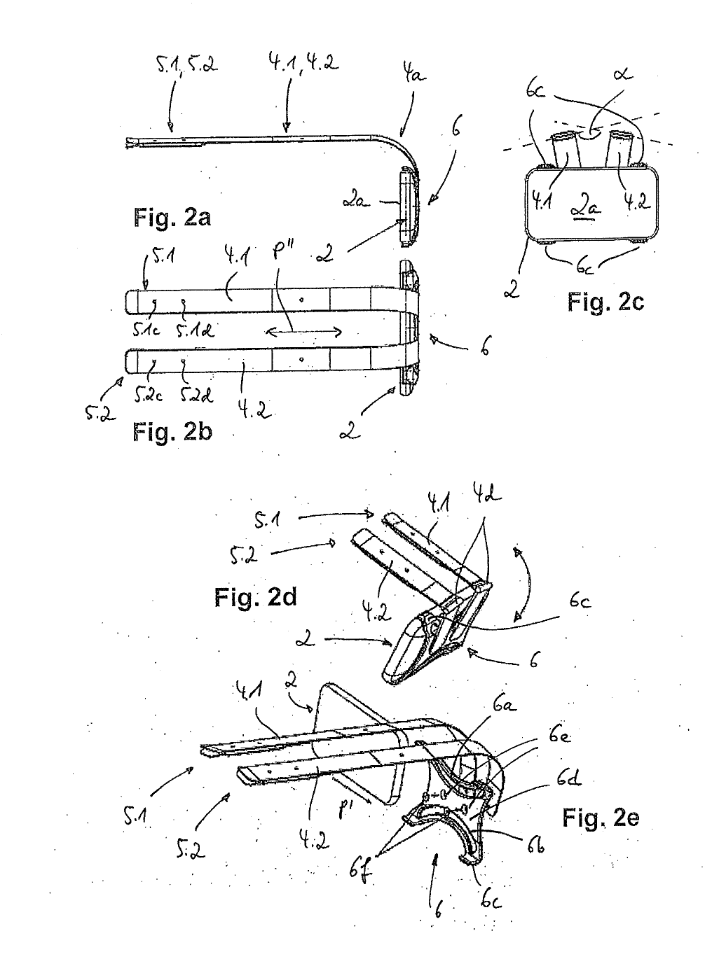

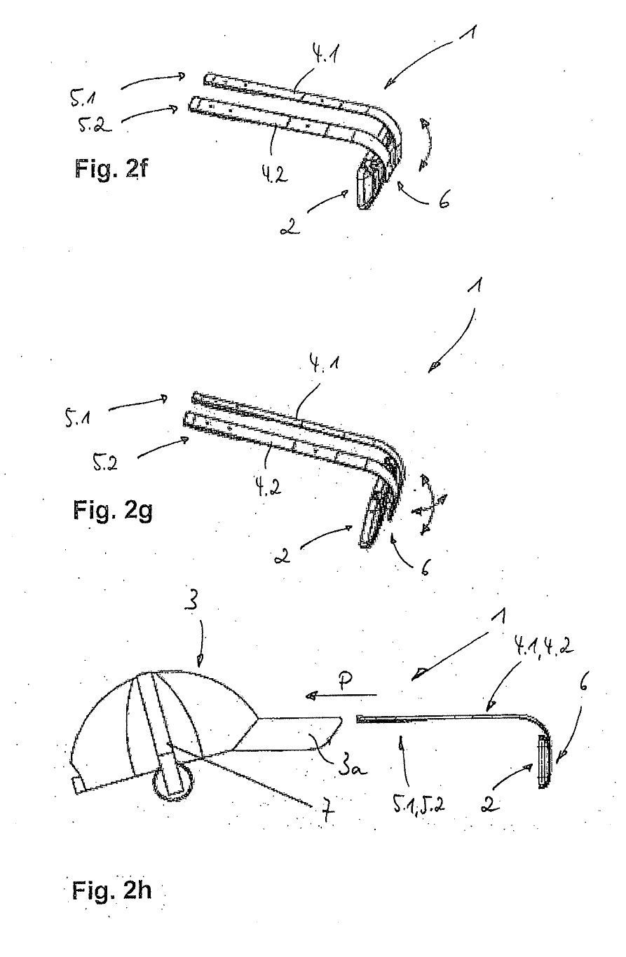

The FIGS. 2a through 2h (FIG. 2 for short) show certain further developments of another embodiment of the retaining device 1 according to the invention. In the present case, only the essential deviations from the above-described embodiment according to FIGS. 1a through 1h are discussed in greater detail.

As particularly discernible from the top view of FIG. 2b the retaining device 1 according to FIG. 2 comprises two parallel retaining arms 4.1 and 4.2, otherwise embodied identical to the retaining arms 4 according to FIG. 1. For an adjustment to the usually slightly curved shape of the cap visor 3a the two retaining arms 4.1, 4.2 according to FIG. 2c, for example, extend not in the same plane but at a certain (obtuse) angle α, see FIG. 2c.

As discernible from FIG. 2e, for example, the two retaining arms 4.1, 4.2 are connected jointly to the receiving and retaining means 6, which for this purpose exhibit a respective number of penetrations 6e.

Otherwise the design and function of the retaining device 1 according to FIG. 2 is completely identical to the above-stated explanations concerning FIG. 1 so that no further description is necessary, here.

For the connection to the head covering 3, accordingly both retaining arms 4.1, 4.2 are pushed with the respective fastening means 5.1, 5.2 onto the cap visor 3a or the like of the head covering 3 (cf. FIG. 2h).

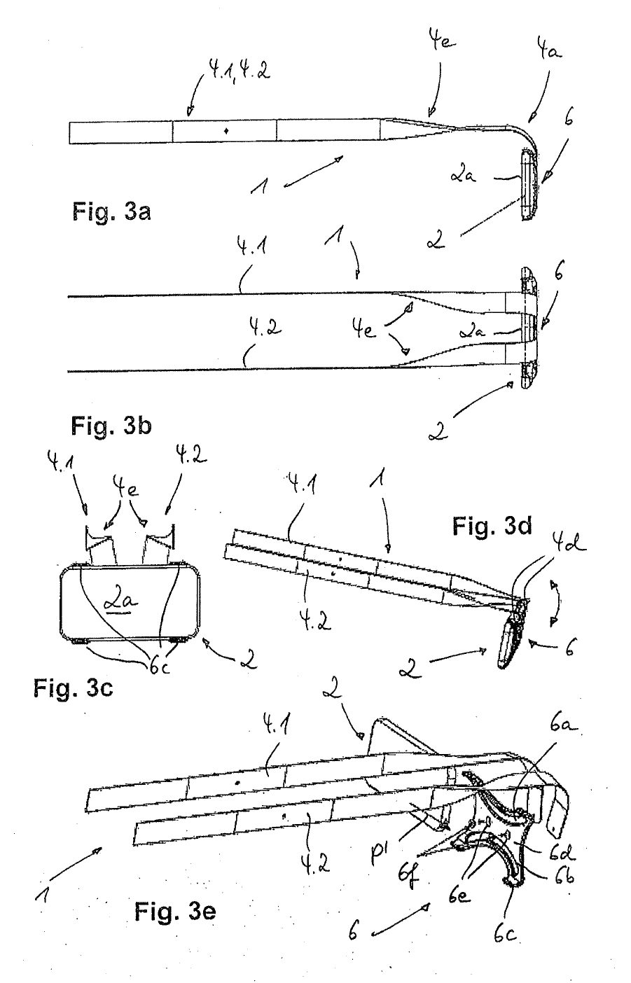

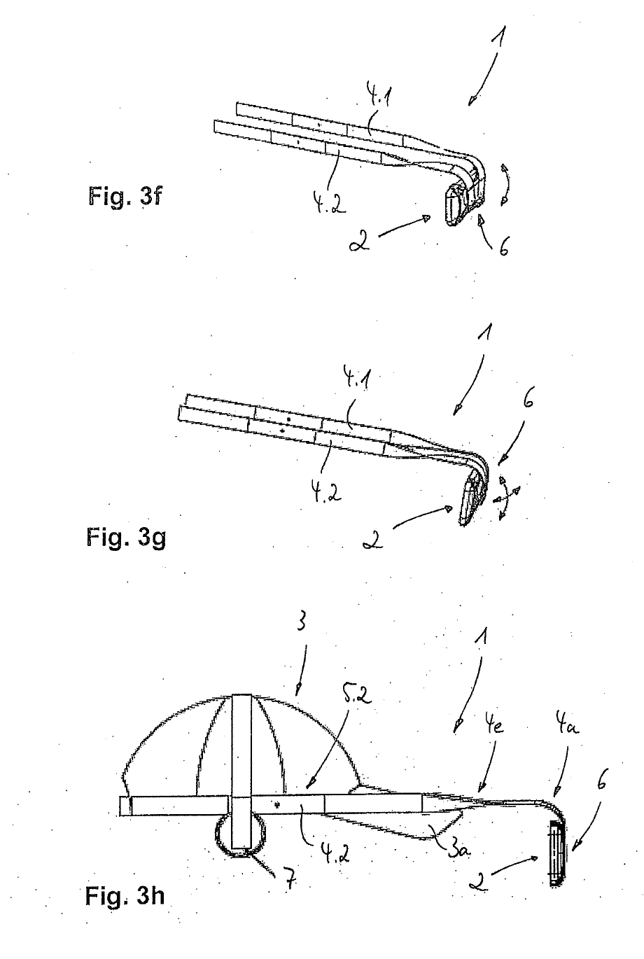

The embodiment according to FIG. 3 (comprising FIGS. 3a through 3h) is largely identical to the above-described embodiment according to FIG. 2. However, here some particulars shall be pointed out:

As discernible from FIG. 3, for example the details 3a and 3b, the retaining arms 4.1, 4.2 are not only curved downwards by 90° at the reference character 4a but further in the direction towards the user (respectively at the left in the detailed illustrations of FIG. 3) twisted at the reference character 4e by 90°. Except for this detail, the embodiment according to FIG. 3 is essentially equivalent to the one of FIG. 2, with another essential exception that no fastening means per se are provided at the retaining arms 4.1, 4.2. As easily discernible from FIG. 3h, in the present embodiment of the retaining device 1 the fastening means are a component of the head covering 3, which as already mentioned therefore becomes a component of the retaining device 1. According to the illustration in FIG. 3h the fastening means, with only one being explicitly shown in 5.2 due to the selected illustration, are each embodied laterally as a pocket or tunnel arranged in the temple area of the head covering 3, in which the retaining arms 4.1, 4.2 are (detachably) inserted or sewn in. This way, the retaining arms 4.1, 4.2 are held in the present embodiment of the retaining device 1 laterally at and/or in the head covering 3, which provides the fastening means. The other embodiments of the retaining device 1 are otherwise equivalent to the ones in FIG. 1 and/or FIG. 2, particularly with regards to the receiving and retaining means 6 and the adjustment possibilities of the retaining arms 4.1, 4.2.

In the embodiment according to FIG. 3 the retaining arms 4.1, 4.2 are preferably embodied from an at least partially flexible material, in order to allow in the lateral area of the head covering 3 an at least partial adjustment to the shape of the head of the user (wearing the cap).

The embodiment according to FIG. 4 (comprising the details FIG. 4a through 4h) is largely identical to the ones in FIG. 3. The only essential difference here comprises that the head covering 3 is not embodied as a baseball cap or the like but as a headband without a visor. The reference character 3′ marks (idealized) the upper head area of the user.

In order to fasten the retaining arms 4.1, 4.2 at the head covering 3, i.e. the headband, the latter once more comprises at least a pocket or a tunnel 5.2, into which the retaining arms 4.1, 4.2 are inserted or sewn in to hold them laterally at the head of the user.

FIG. 5 (comprising the details 5a through 5e) shows a particularly simple embodiment of the retaining device 1 according to the invention in which the retaining arms 4.1, 4.2 are embodied from a preferably metallic tubular or wire material. The retaining arms 4.1, 4.2 can here be formed in one piece from a single wire element.

In the following, some particulars of the embodiment according to FIG. 5 are explained in greater detail.

As particularly discernible from the side view in the (partial) FIG. 5a the retaining arms 4.1, 4.2, starting from their end facing away from the receiving and retaining means, exhibit first a straight progression. Subsequently, at the reference character 4f, first a bend downwards follows by approximately 45° and then, at the reference character 4g, another bend again by approximately 45° upwards so that the progression of the retaining arms 4.1, 4.2 is subsequently once more parallel in reference to the originally straight progression. Furthermore, the retaining arms 4.1, 4.2 are embodied like a flange in one piece or, at the reference character 4i, in a mountable fashion, and merge in the area of the receiving and retaining means 6 such that overall a U-shaped, flange-like progression develops in the top view (cf. FIG. 5b).

The receiving and retaining means 6 are provided in the area of the central U-legs 4h , which may occur in an particularly simple fashion, for example, such that the retaining arms 4.1, 4.2 each are laterally inserted in a respective recess of the receiving and retaining means 6, as indicated in FIG. 5d. Due to the preferably round cross-section of the retaining arms 4.1, 4.2, this way an easy pivoting of the receiving and retaining means 6 can be realized in the direction of the dual arrow in FIG. 5d.

The fastening means to connect the retaining arms 4.1, 4.2 with the head covering 3 according to FIG. 5e are once more embodied as a part of the head covering 3, which therefore represents a component of the retaining device. Preferably, in this context once more at least a lateral tunnel or a lateral pocket 5.2 is provided in the temple area of the head covering 3. Within the scope of an embodiment as simple as possible in the retaining device 1, in the above-mentioned area simply a series of loops or eyelets may be provided, into which the retaining arms 4.1, 4.2 are respectively inserted. Here, a VELCRO connection is also possible.

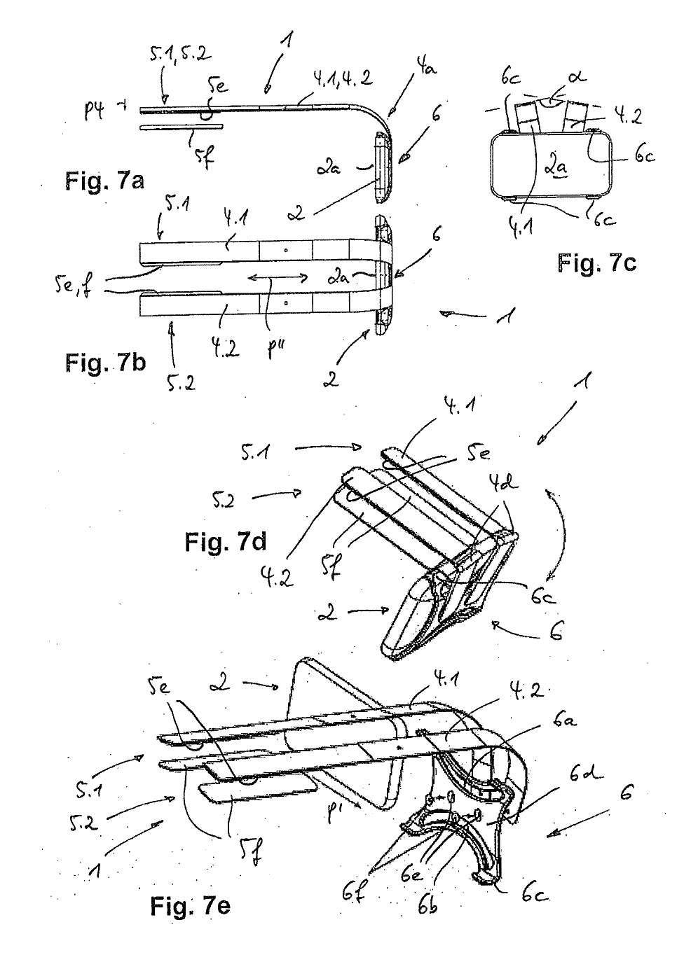

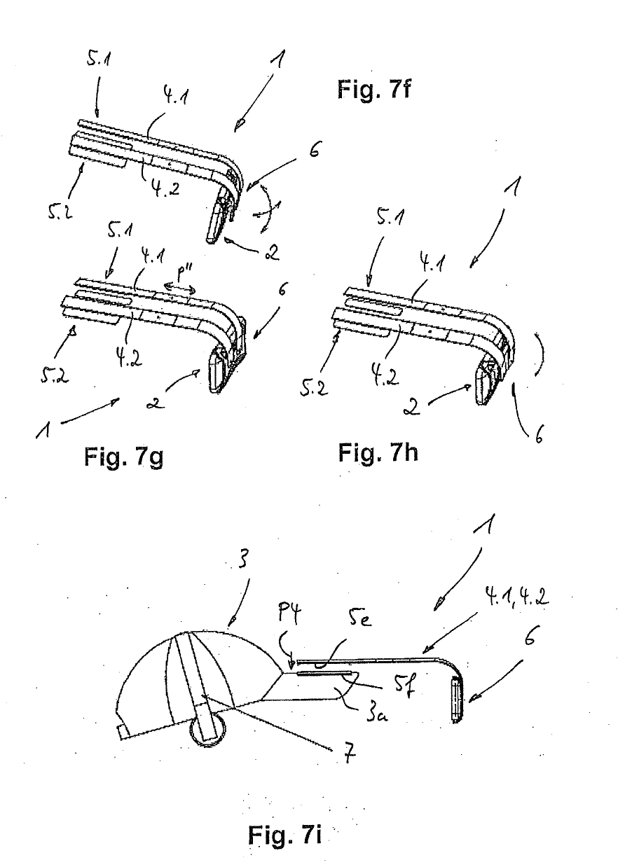

As indicated in FIGS. 5a and 5b by a separating line T, the retaining device 1 may also be embodied shortened in the area of the retaining arms 4.1, 4.2. Such an embodiment is suitable for the fastening directly at the cap visor 3a, particularly by way of sewing, riveting, adhering, or also via a VELCRO connection. In the following, the latter fastening variant is described in greater detail with reference to FIG. 7. FIG. 8 also shows a shortened variant of the retaining device 1, which is generally equivalent to the above-discussed variant when separated along the separation line T.

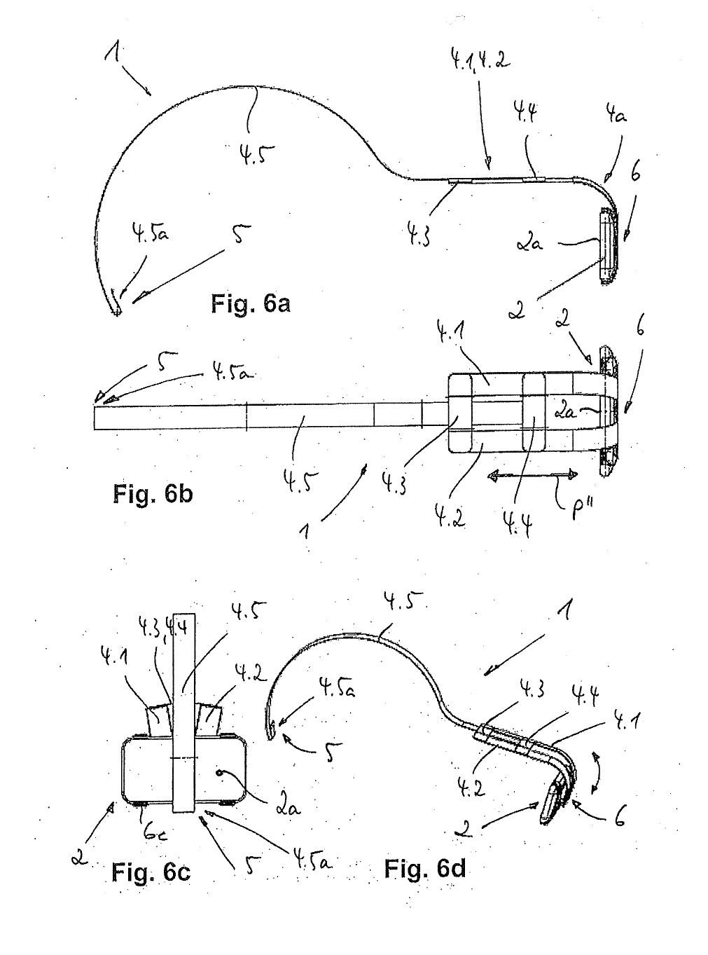

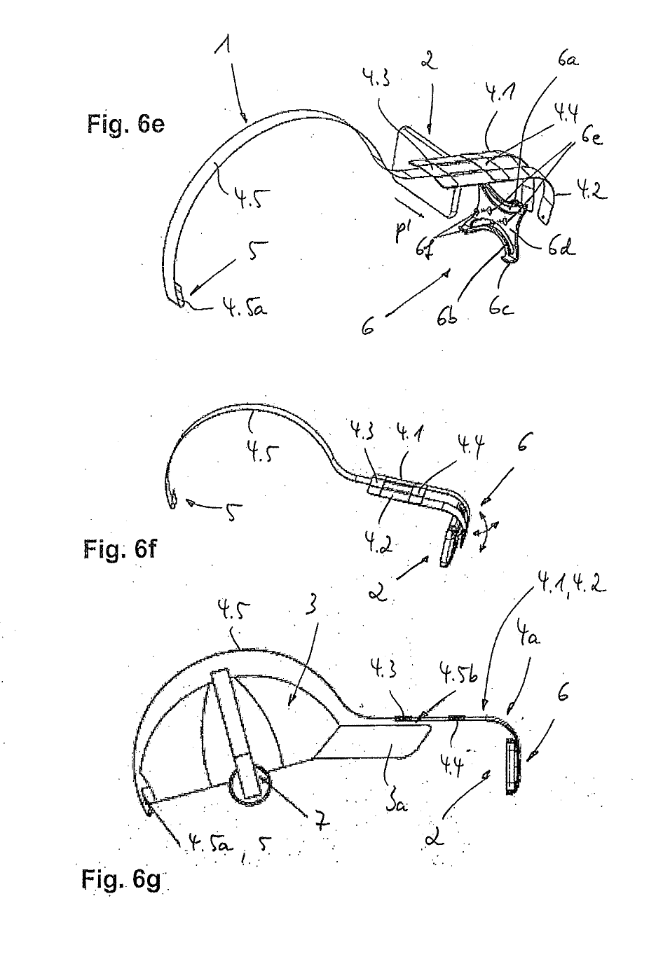

FIG. 6 (comprising the partial FIGS. 6a through 6g) shows a particular embodiment of the retaining device 1 according to the invention, which is provided for an “over the head assembly”.

In the following, the particular features of this embodiment are discussed in greater detail, which in the area of the receiving and retaining means 6 as well as their connection to the retaining arms 4.1, 4.2 are essentially equivalent to the embodiment according to FIG. 2.

Contrary to FIG. 2, the retaining arms 4.1, 4.2 embodied shortened in the direction towards the head of the user are not equipped themselves with the fastening means 5.1, 5.2, but are connected to teach other via lateral connection parts 4.3, 4.4 with the lateral connection parts 4.3, 4.4 each exhibiting a penetration in the area between the retaining arms 4.1, 4.2, into which another retaining arm 4.5 can be inserted centrally into the area between the retaining arms 4.1, 4.2 and is here held in an adjustable fashion. The additional retaining arm 4.5 comprises at one end, by which it is inserted into the above-mentioned lateral connection parts 4.3, 4.4, an essentially straight, flat progression. Towards its other, free end it is curved approximately semi-circularly and ends at its free end in a hook-shaped 180° bend 4.5a.

The use of the retaining device according to FIG. 6 is here as follows:

Using the bend 4.5a the retaining arm 4.5 is fastened and/or engaged in the area of the back of the head at the head covering 3 (cf. FIG. 6h), which for this purpose shows a suitable fastening structure in the areas mentioned, which preferably is formed by the adjustment tape of a conventional baseball cap or the like. Of course, in an arbitrary type of head covering a dedicated fastening structure may be provided in this area, e.g., in the form of a ring, an eyelet, or a flap, which the retaining arm 4.5 can engage with the bend 4.5a.

Subsequently the retaining arm 4.5 with its curved area is guided over the head and/or the head covering 3 of the user and then contacts the head covering 3 preferably in the area of the lateral connection part 4.3, 4.4 and/or the parallel retaining arm 4.1, 4.2 at the reference character 4.5b, for example at the visor 3a of a baseball cap.

As discernible for one trained in the art it is generally also possible, instead of the retaining arms 4.1, 4.2 and the lateral connection elements 4.3, 4.4, to provide a single retaining arm 4.5, extended towards the front, which otherwise may be embodied in the frontal area essentially like the embodiment in FIG. 1.

Furthermore, of course the object of FIG. 6 may also use an embodiment of the retaining arm 4.5 and/or the retaining arms 4.1, 4.2 with joint(s) 4d according to the FIGS. 1d through 4d.

In other areas one trained in the art also may freely combine individual features of the above-described embodiments according to the FIGS. 1 through 8 without any inventive activity.

FIG. 7 (comprising the partial FIGS. 7a through 7i) shows another embodiment of the retaining device 1 according to the invention, which largely is equivalent to the embodiment shown in FIG. 2, so that here only a few particulars need to be described in greater detail.

They relate to the fastening means 5.1, 5.2 for fastening a retaining device 1 and/or the retaining arms 4.1, 4.2 at the head covering 3 with a visor 3a, shown exemplary in FIG. 7i.

In the embodiment according to FIG. 7 the fastening means 5.1, 5.2 are embodied in the form of VELCRO connections. They respectively comprise one hook element 5e, which cooperates with a loop element 5f. Preferably the hook elements 5e are each arranged at the bottom of the retaining arms 4.1, 4.2, while the loop elements 5f being located on the top of the visor of the cap (cf. FIG. 7i). However, the opposite arrangement is also possible. Furthermore, hook and/or loop elements may also be provided at the bottom of the visor of the cap. Instead of two separate hook and/or loop elements a single, continuous element may also be used on the visor of the cap.

Of course, such a connection between the retaining device 1 and the head covering 3 is generally also suitable for the use in the other embodiments of the present invention shown, particularly for the lateral mounting of the retaining arm according to FIG. 5 or instead of and/or in addition to engaging in the area of the back of the head in the embodiment according to FIG. 6. Here, the hook or loop element may extend centrally over the entire head covering 3.

For the intended use of the retaining device according to FIG. 7 it is connected via its retaining arms 4.1, 4.2 simply in the direction of the arrow P4 shown in FIG. 7a and FIG. 7i via the described VELCRO connection to the head covering 3, i.e. the hook elements 5e and the loop elements 5f are made to contact each other.

Finally, FIG. 8 (comprising partial FIGS. 8a through 8f) shows an embodiment of the present invention, which is based on those described above in detail based on FIG. 5. In this context it has already been discussed that the embodiment according to FIG. 5 may be embodied shortened by separation at the separation line T and in this context is particularly suitable for fastening at a visor of a cap or a sun shade. This is shown in detail in FIG. 8.

According to FIGS. 8a through 8c the retaining arms 4.1, 4.2 are produced from the same material as in the embodiment according to FIG. 5, however they otherwise extend similar to the embodiment according to FIG. 2. In other words, the retaining arms 4.1, 4.2 extend downwards after the bend at the reference character 4a and inwardly towards a common point at which they are connected via the receiving and retaining means 6. Here, too, the retaining arms 4.1, 4.2 may be embodied in one piece. At the common point, a thickening (not explicitly shown) or even a U-shaped bend may be provided which serves to accept a screwing means for fastening the receiving and retaining means 6.

The receiving and retaining means 6 according to the illustration in FIG. 8e are formed by an X or cross-shaped part, which at its free bar end in turn shows slightly inwardly curved retaining projections 6c, already mentioned repeatedly. The central penetration 6e serves to the (detachable) connection to the ends of the retaining arms 4.1, 4.2, preferably via a screw connection.

The receiving and retaining part according to FIG. 6 in FIG. 8e can particularly be embodied as a light-metal punched part, preferably comprising aluminum.

FIG. 8f shows the fastening of the above-described retaining device 1 in the area of the visor of the baseball cap 3a with an otherwise commercial baseball cap 3. The fastening may occur by way of sewing, rivets, screws, adhesion, insertion, or by a VELCRO connection.

Here, it shall once more be pointed out that the head covering 3 shown in FIGS. 1 through 8, particularly in FIGS. 1h through 4h, 5e, 6g, 7i, and 8f not necessarily needs to be a part of the retaining device according to the invention. The latter can also exist without any head covering 3, acting independently. However, it is beneficial to provide a head covering as a part of the retaining device according to the invention when the head covering, in order to cooperate with the remaining retaining device must be adjusted in its design in a certain fashion, as is the case for example according to FIGS. 3h through 5h.

The sound system 7, as already mentioned, is only an optional component of the present invention. In particular in the embodiments according to FIG. 3 and FIG. 4 the optional sound system 7 may be fastened at the retaining arms 4.1, 4.2 extending lateral along the head.

The retaining device 1 and here particularly the retaining arm 4 and/or the retaining arms 4.1, 4.2, 4.5 with their parts as well as the receiving and retaining means 6 may be provided as separate parts for storage, transportation, and packaging purposes, which advantageously are combined only by the end user in order to form the finished retaining device.

For reasons of stability the retaining arms 4.1, 4.2 may extend in the two-arm variants shown also crossing each other.

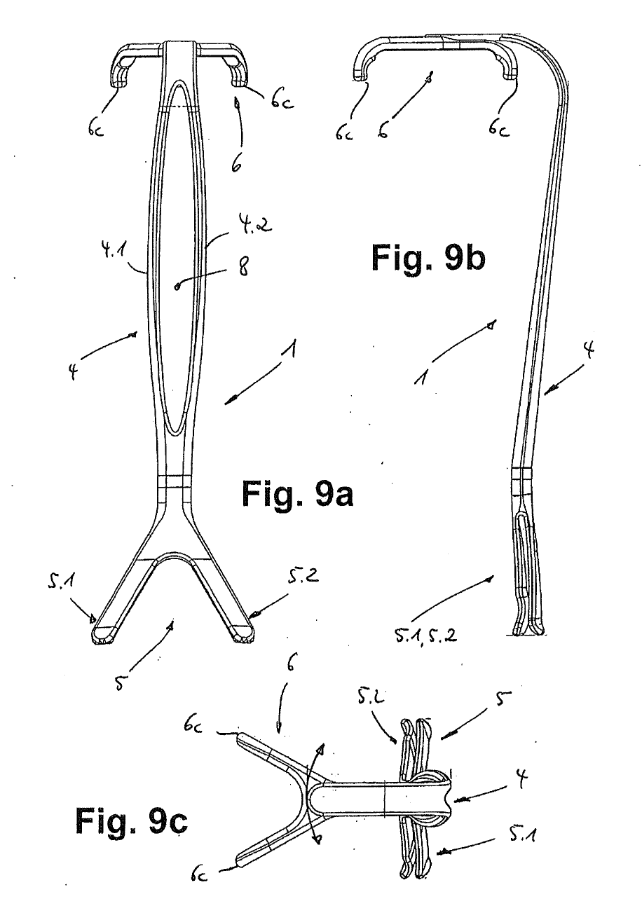

FIGS. 9a through 9c show views of another embodiment of the retaining device 1 according to the invention. FIG. 9a shows a top view, FIG. 9b shows a side view, and FIG. 9c shows a front view displaying the side of the retaining arm 4 facing away from the wearer. The entire arrangement of retaining arm 4, fastening means 5, as well as receiving and retaining means 6 may be embodied in a particularly light-weight plastic construction, with particularly the V-shaped clamping means 5.1, 5.2, extending away from each other, and the retaining arm 4 being embodied integrally in one piece. The retaining arm 4 also splits sectionally into two parallel extending, curved retaining arms 4.1, 4.2, which define an approximately elliptic free space 8 between each other, which particularly contributes to save weight. However, it is also possible in the area of the free space 8 to provide an additional, appropriately shaped (plastic) part (not shown), which for example may be provided with printed advertisement. The fastening means 5 (in FIGS. 9a-3 also differently called fastening means 5.1, 5.2) are equivalent in their function essentially to the fastening means according to, for example, FIG. 2 so that there is no need for further explanation, here.

The receiving and retaining means 6 differ from the ones in FIG. 2 essentially by their overall Y-shaped embodiment, which also requires no detailed discussion.

FIG. 10 (comprising the partial FIGS. 10a through 10c) discloses however another essential aspect of the present invention, with the retaining device here being marked with the reference character 1′ and embodied as a retaining device for fastening at an air-conditioning register of a motor vehicle, which shall be explained in greater detail in the following. Here, FIG. 10a shows a front view displaying the dashboard and/or the center console of a motor vehicle, FIG. 10b a cross-section approximately along the line B-B in FIG. 10a, and FIG. 10c a schematic illustration to explain the function, which is essentially equivalent to the view along the line C-C in FIG. 10a.

In FIG. 10a the reference character 9 marks the dashboard and/or the center console of a typical motor vehicle. Here, a ventilation or air-conditioning duct 10 is arranged, which usually comprises an adjustable air-conditioning register 11 with horizontal bars 11a and vertical bars 11b, which are typically arranged like a rectangular grid. The retaining device 1′ according to the invention serves to fasten a multimedia terminal, not shown in FIG. 10, in the area of the air-conditioning duct 10 and/or at the air-conditioning register 11.

For this purpose, the retaining device 1′, as already discernible in FIG. 10a, comprises a support part 12, which in the present case shows four support arms 12.1-12.4, arranged like the letter X. Here, the support arms 12.1 and 12.3 and/or 12.2 and 12.4 are each connected to each other in one piece, resulting in the above-mentioned X-arrangement. The support arms 12.1-12.4 are linked to a central retaining structure 13 and pivotal in reference to each other according to the dual arrow in FIG. 10a, allowing an adjustment to various air-conditioning geometries. The other arrows E, for reasons of clarity drawn only in the area of the support arms 12.1 and 12.4, symbolize the adjustability of the support arms 12.1-12.4 in the direction of their respective longitudinal extension, which allows an additional adjustment to the geometry of the air-conditioning duct.

Furthermore, a retaining arm 4 is discernible from FIG. 10a, which in the present case extends starting at the central fastening structure 13 first forwardly and then parallel in reference to the dashboard 9 (upwardly) and which shows connection means 14, drawn only schematically, for a detachable connection to the receiving and retaining means for a multimedia terminal to be fastened. Both the receiving as well as the fastening means, and the multimedia terminal are not shown in FIG. 10 for reasons of clarity. For example, they can generally be equivalent to the embodiment according to FIG. 1 or FIG. 2 without the present invention being restricted to such an embodiment, though.

The connection means 14 preferably represent a part of a ball-and-socket joint with the receiving and retaining means (not shown) then accordingly comprising another joint part. The present invention is not limited at all to the above-mentioned exemplary type of joints so that here all other types of joints and connections known to one trained in the art may be used, which may not only be mechanical in nature but also may be of a magnetic or adhesive nature.

The cross-section according to FIG. 10b illustrates additional essential features of the retaining device 1′ according to the invention: As discernible from FIG. 10b, an oblong anchoring part 15 with a hooked end 15a is provided in a mechanically active connection with the retaining arm 4 (cf. also FIG. 1c), which can be guided between the bars 11a, 11b of the air-conditioning register 11. In order to ensure this, a respective dimension of the hooked end 15a may not be greater than the distance between two neighboring horizontal or vertical bars 11a, 11b. Advantageously, in this context the oblong anchoring part 15 is rotational about its longitudinal axis in order to this way allowing to thread the hooked end 15 between the bars 11a, 11b of the air-conditioning register 11 when required. The hooked end 15a is embodied to engage behind a bar, in the present case a vertical bar 11b of the air-conditioning register 11, and this way appropriately anchoring the anchoring part 15. As shown in FIG. 10c, the hooked end 15a may also be bent backwards in the direction of the remaining anchoring part 15 in order to engage this way the rear narrow side of the bar 11b in an essentially form-fitting fashion. As already mentioned, due to the rotary embodiment of the anchoring part 15 the anchoring function according to the invention is not limited to engaging a vertical bar 11b (cf. FIG. 10c). In this context it is particularly advantageous when the retaining arm 4 and the anchoring part 15 according to a preferred embodiment of the present invention are embodied in two parts, for example by providing a suitable screw-connection with an internal thread and an external thread (not shown). This way, it is ensured on the one hand that the retaining arm 4 and with it the connection means 14, regardless of the orientation of the connection part and/or the connection part 15 and/or the hooked end 15a, always exhibit the desired orientation with regards to the connection to the receiving and retaining means (not shown) for the multimedia terminal. Additionally this way an effective longitudinal extension of the unit comprising retaining arm 4 and anchoring part 15 can be adjusted to different geometries of the air-conditioning register.

In order to ensure a secure anchoring of the described retaining device 1′ at the air-conditioning register 11 the support part 12 with its support arms 12.1-12.4 is arranged thereon displaceable in reference to the hooked end 15a of the anchoring part 15 and/or the retaining arm 4, which is symbolized in FIG. 10c by the dual arrow V. This way, the distance A between the support part 12 and the hooked end 15a can be adjusted until it essentially matches a distance A between the front area of the dashboard and/or the center console 9 and the rear narrow side of the bars 11a, 11b. In reference to the retaining device 1′ the respective distance A′ between the base of the hooked end 15a and the support elements 12′ of the support part 12 is defined, with the support elements 12 being arranged at the free ends of the support arms 12.1-12.4. The support elements 12′ are preferably embodied from a soft, oscillation damping material, such as foamed rubber or the like. By pulling the retaining arm 4 and/or the anchoring part 15 in the direction of the arrow Z in FIG. 10c and/or by pressing in the direction of the arrow D upon the support part 12 this way a tightening of the retaining device 1′ can be achieved between the air-conditioning register 11 and the dashboard and/or the center console 9. The curved or bent embodiment of the support arms 12.1-12.4 shown increases the tightening force by the spring effect connected thereto.

In order to permanently fixate the relative arrangement of the anchoring part 15, 15a and the support 12 achieved this way in a detachable manner, a fixation means 16 is provided according to the schematically displayed illustration in FIGS. 10b and 10c, which acts in a suitable fashion upon the retaining arm-anchoring part arrangement 4, 15 particularly mechanically or magnetically, in order to prevent that the support part 12 moves away from the dashboard and/or the center console 9 on the above-mentioned arrangement which would coincide with a loss of clamping force. In the schematic illustration according to FIG. 10c the fixation means is embodied as spring-loaded clamping or latching means, which can be unlocked by pressing upon the operating element 16a shown in order to tighten and/or to loosen the retaining device 1′ and to remove it from the air-conditioning register 11.

However, the present invention is not limited to the above-described exemplary embodiment of the fixation means 16. A simple alternative embodiment provides in this context for the operating element 16a to be embodied in the form of a simple latching pin or screw, which can be inserted or screwed into suitable penetrations (not shown) in the retaining arm 4 and/or the anchoring part 15.

At the reference character 17 the anchoring part 15 may exhibit in the area of the hooked end 15a a predetermined breaking point with for example lower material thickness so that in case of excessive tightening force no damage of the respective bar 11a, 11b can occur but “only” the hooked end 15a being torn off. In this context it is advantageous for the anchoring part 15 to be embodied as a separate exchangeable part in order to allow exchanging it independent from the retaining arm 4.

In particular the support part 12 with the above-mentioned support arms 12.1-12.4 is embodied from a plastic material within the scope of the present invention, with the use of non-fiberglass reinforced polyamide (PA) proved to be particularly advantageous, without being restricted thereto.

FIG. 11 (comprising partial FIGS. 11a through 11c) shows a particular embodiment of the receiving and retaining means 6 as a separately traded unit, which generally may be used in all retaining devices 1, 1′ shown in connection with the respective retaining arm 4.

FIG. 11a shows schematically the receiving and retaining means 6, which generally may be equivalent to the above-described embodiments. They serve to receive and retain a multimedia terminal 2, also shown only schematically. In the following, as well as generally according to the wording of the present description, the side of the receiving and retaining means 6 mutually engaging the multimedia terminal 2 is called the “front”. According to this wording, at the rear of the receiving and retaining means 6 connection means 14′ are arranged, which beneficially are embodied complementary in reference to the two already discussed connection means 14 (cf. FIG. 10) at the retaining arm 4 in order to this way allowing a detachable connection between the retaining arm 4 and the receiving and retaining means 6. According to the schematic illustration in FIG. 11a the above-mentioned connection is here realized in the form of a pivotal joint, and for this purpose a first joint part 14a is provided at the retaining arm 4 with a penetration 14b and a second joint part 14a′ with a penetration 14b′ at the receiving and retaining means 6. The above-mentioned joint parts 14a, 14a′ can also be mechanically interacting, with the above-mentioned penetrations 14b, 14b′ being aligned to each other such that via an inserted rod-shaped connection part 18 the desired (pivotal) connection develops between the retaining arm 4, on the one side, and the receiving and retaining means 6, on the other side. This is indicated in FIG. 11via a dot-dash line. Accordingly, the receiving and retaining means 6 can be separated from each other after the removal of the connection part 18. This status is shown in FIG. 11b.

As furthermore discernible, at their rear the receiving and retaining means 6 exhibits a recess in the form of a blind hole 19, embodied for partially accepting the connection part 18 by a simple plug-in connection. Here, the recess 19 is embodied such that it extends the connection part 18 after insertion at an angle ε, with ε preferably being below 90°. This way, without any major construction expense a table fastening can be realized for the mobile multimedia terminal 2, based on the receiving and retaining means 6. The connection part 18 may be embodied at its end not inserted in a suitable fashion such that it ensures secure placement, for example by a suitable slip-resistant coating, an enlarged embodiment, or the like.

FIG. 11c shows a variant of the embodiment of the receiving and retaining means 6 described above based on FIG. 11b. In addition to the connection part 18 shown in FIG. 11a and FIG. 11b and/or instead thereof, in the embodiment according to FIG. 11c a pivotal support 18′ is provided, which is linked at the reference character 18″ at the rear of the receiving and retaining means 6 and pivotal in the direction of the dual arrow according to FIG. 11c. The pivotal support 18′ may be provided, as already mentioned, in addition to the inserted support according to FIG. 11b in order to ensure a secure stand of the receiving and retaining means 6. Furthermore, there is the chance to provide the recess 19 shown in FIG. 11b in the area of the pivotal link 18″ according to FIG. 11c so that then the pivotal support 18′ could be realized by the inserted connection part 18 according to FIG. 11b.

In a suitable embodiment of the retaining arm 4 (cf. FIG. 11a) the receiving and retaining means 6 according to FIG. 11 can be used both within the scope of the (cap) fastening device 1 as well as the (air-conditioning register) fastening device 1′. This once more illustrates the uniform, modular character of the present invention, which provides system components adjusted to each other for the flexible use of mobile multimedia terminals.

1. A retaining device (1) for a mobile multimedia terminal (2), comprising:
at least one retaining arm (4, 4.1, 4.2, 4.5);
fastening means (5) arranged at a first end of the retaining arm for fastening the retaining arm to a head covering (3) so that the retaining arm extends from the head covering forward in a direction of a user;
receiving and retaining means (6) for the multimedia terminal arranged at a second end of the retaining arm;
wherein the receiving and retaining means for the multimedia terminal are arranged or adjustable in reference to the retaining arm such that at least one graphic display device (2a) of a multimedia terminal received therein after fastening of the retaining arm to the head covering is located essentially centrally in a field of view of a user.

2. The retaining device (1) according to claim 1, wherein the retaining arm (4, 4.1, 4.2, 4.5) is adjustable such that the receiving and retaining means (6) for the multimedia terminal (2) is at a distance from 10 cm to 40 cm from an eye of a user, with the retaining device preferably comprising two parallel arranged, essentially identical retaining arms (4.1, 4.2), with the receiving and retaining means (6) for the multimedia terminal (2) being arranged at their second ends.

3. A retaining device (1) according to claim 1, wherein the receiving and retaining means (6) for the multimedia terminal (2) are fastened to the retaining arm (4, 4.1, 4.2, 4.5) in an articulate fashion.

4. A retaining device (1) according to claim 1, wherein the retaining and fastening means (6) for the multimedia terminal (2) is embodied as a holding cup, in which the multimedia terminal can be inserted or clipped.

5. A retaining device (1) according to claim 1, wherein the receiving and retaining means (6) for the multimedia terminal (2) is adjustable to differently sized multimedia terminals.

6. A retaining device (1) according to claim 1, wherein the receiving and retaining means (6) for the multimedia terminal (2) is fastened detachably to the retaining arm.

7. A retaining device (1) according to claim 1, wherein the retaining arm (4, 4.1, 4.2, 4.5) is embodied essentially stiff, at least in a section facing the receiving and retaining means (6) for the multimedia terminal (2), with the retaining arm in said section preferably comprising at least one joint (4d) so that the receiving and retaining means for the multimedia terminal can be moved out of a field of view of the user.

8. A retaining device (1) according to claim 1, wherein the retaining arm (4, 4.1, 4.2, 4.5) is embodied at least at a section facing away from the receiving and retaining (6) for the multimedia terminal (2) in a flexible fashion.

9. A retaining device (1) according to claim 1, wherein the retaining arm (4, 4.1, 4.2, 4.5) comprises an angle or a bend (4a, 4e, 4f, 4g) in an area of the second end in order to position the receiving and retaining means (6) for the multimedia terminal (2) in the field of view of the user, with an extent of the angle or bend ranging from 70° to 110°.

10. A retaining device (1) according to claim 1, wherein the retaining arm (4, 4.1, 4.2, 4.5) is embodied at least sectionally essentially flat and comprising plastic, or the retaining arm at least sectionally exhibits a round cross-section and made from metal.

11. A retaining device (1) according to claim 1, wherein the fastening means (5) are embodied as at least two spring-elastic clamping parts (5a, 5b) acting opposite each other, by which the retaining arm (4, 4.1, 4.2, 4.5) can be fastened in a clamping fashion at a visor, a shade, or a brim (3a) of a head covering (3).

12. A retaining device (1) according to claim 1, wherein the fastening means (5) comprise at least one penetration (5c, 5d) in the retaining arm (4, 4.1, 4.2, 4.5) as well as connection means that can be guided through the penetration which cooperate with at least one complementary structure in the visor, shade, or brim area (3a) of the head covering (3) in order to fasten the retaining arm at the head covering.

13. A retaining device (1) according to claim 1, wherein the fastening means (5) comprise a structure (4.5a) bent with regards to an extension of the retaining arm (4.5), which for engaging a suitable structure, an adjustment tape in an area of a back of the head of a head covering (3) is embodied to fasten the retaining arm to the head covering, with the retaining arm between the fastening means and a second end comprises at least one section formed complementary to the head covering.

14. A retaining device (1) according to claim 1, wherein head covering (3) comprises a baseball cap, which as the fastening means (5) comprises at least one insert (5.2) extending to an area of a back of the head each approximately at a height of a user's temples, in which one respective retaining arm (4.1, 4.2) is inserted, with the retaining arms being mobile in a tunnel between an inserted resting position and an extended operating position.

15. A retaining device (1) according to claim 1, wherein a loud speaker device (7) is fastened at the retaining arm (4.1, 4.2) or to the head covering (3), with the loud speaker device cooperating in terms of signaling with the mobile multimedia terminal (2).

16. A retaining device (1) according to claim 1, wherein at least one pin-shaped connection part (18) is provided for detachable connection of the receiving and retaining means (6) for the multimedia terminal (2) with the retaining arm (4), which can be inserted on the one side in aligned penetrations (14b, 14b′) to the receiving and retaining means (6) and on the other side to the retaining arm (4), with at least one recess (19) being provided at a rear of the receiving and retaining means for partially accepting the connection part in a direction of longitudinal extension thereof so that the connection part in an inserted state extends at a finite angle (ε), ranging from 30° to 150°, in reference to the rear of the receiving and retaining means.

17. A retaining device (1) according to claim 1, wherein at least one pivotal support part (18′) is provided at a rear of the receiving and retaining means (6), which in its pivoted state extends at a finite angle (ε) ranging from 30° to 150°, in reference to the rear of the receiving and retaining means.

18. A receiving and retaining device (6) for a mobile multimedia terminal (2) comprising connection means (14′) for detachable connection to a retaining arm (4) arranged at the rear, for connecting the retaining arm (4) of the device (1) according to claim 1 with the receiving and retaining means (6) for the multimedia terminal (2) comprising a receiving cup, in which the multimedia terminal can be inserted or clipped in.

19. A receiving and retaining device (6) according to claim 18, wherein the connection means (14′) are embodied for an articulate connection to the retaining arm (4).

20. A receiving and retaining (6) according to claim 18, wherein the connection means (14′) comprises a pivot joint or a ball-and-socket joint.

21. A retaining device (1′) for a mobile multimedia terminal (2), comprising:
at least one retaining arm (4);
fastening means (5′) arranged at a first end of the retaining arm for fasting the retaining arm to an air-conditioning register (11) in an area of a dashboard or a center console (9) of a motor vehicle;
connection means (14) arranged at a second end of the retaining arm for connecting the multimedia terminal;
the fastening means (5′) comprise at least the following elements:
at least one oblong anchoring part (15) with at least one hooked end (15a), which can be guided between bars (11a, 11b) of the air-conditioning register (11), with the hooked end (15a) being embodied for an essentially form-fitting engagement of a rear narrow side of at least one bar;
at least one support part (12) with at least one support element (12′) for supporting outside the air-conditioning register (11) on a dashboard or the center console, which is displaceable (V) in reference to the hooked end (15a) of the anchoring part (15);
fixing means (16) for the detachable fixation of a relative arrangement of the hooked end (15a) and the support part (12).

22.-33. (canceled)
